(19) United States
(12) Patent Application Publication
(10) Pub. No.: US 2012/0267154 A1
(43) Pub. Date: Oct. 25, 2012

(54) Low Resistance, Multi-Contact Point Pin

(75) Inventors: Tony C. Sass, Fuquay Varina, NC (US); Paul A. Wormsbecher, Apex, NC (US)

(73) Assignee: INTERNATIONAL BUSINESS MACHINES CORPORATION, ARMONK, NY (US)

(21) Appl. No.: 13/090,586

(22) Filed: Apr. 20, 2011

(51) Int. Cl. H05K 1/11; H01R 43/16; H01R 13/02

(52) U.S. Cl. 174/261; 439/884; 29/874

(57) ABSTRACT

A low resistance, multi-contact point pin, configured for insertion into a pin receptacle having an electrically conductive plating, where the pin includes: a surface and more than one electrically conductive extrusion from the surface of the pin, with each extrusion extruding substantially orthogonal to a direction of insertion of the pin into the pin receptacle, and where the extrusions configured to electrically couple, with parallel resistance, the pin to the electrically conductive plating of the pin receptacle.

### BACKGROUND OF THE INVENTION

1. Field of the Invention

The field of the invention is pins, or, more specifically, low resistance, multi-contact point pins, connectors that include arrays of low resistance, multi-contact point pins, methods of manufacturing low resistance, multi-contact point pins, and printed circuit boards configured to receive low resistance, multi-contact point pins.

2. Description of Related Art

A compliant pin is a press-fit, solder-free electrical interconnect to a printed circuit board (PCB). The mechanical and electrical interfaces between a electrical source and a PCB are made with a spring-like compliant pin and a plated thru-hole via. For explanation, FIG. 1 sets forth a cross-section of a compliant pin (102) of the prior art. The prior art compliant pin (102) of FIG. 1 is configured for insertion into a plated via (106) of a PCB (108). The pin (102) is an ‘eye-of-the-needle’ type with a hole or ‘eye’ (114) in the center of the pin (102) and two flanges (110, 112) on either side of the eye (114). The diameter of the pin (112) from flange-to-flange is greater than the diameter of the plated via (106) such that, upon insertion, each flange (110, 112) is depressed toward the center of the eye (114). The depressed flanges (110, 112) physically hold the pin in place and provide two distinct electrical points of contact (104). As such, compliant pins (102) of the prior art may be solder-free interconnects.

Such pins of the prior art are typically employed in arrays of a single terminal connector. For example, a power supply connector may terminate to a PCB with a connector that includes 16 or 32 compliant pins (102). The use of multiple compliant pins, especially in a grid-like array, reduces resistance introduced into the signal path by any single pin. Further reduction of resistance introduced by such pins may be beneficial in many applications.

### SUMMARY OF THE INVENTION

Low resistance, multi-contact point pins are described in this specification. The pin is configured for insertion into a pin receptacle having an electrically conductive plating and includes a surface and electrically conductive extrusions from the surface of the pin, with each extrusion extruding substantially orthogonal to a direction of insertion of the pin into the pin receptacle, and the extrusions configured to electrically couple, with parallel resistance, the pin to the electrically conductive plating of the pin receptacle.

Also described in this specification are printed circuit boards configured in accordance with embodiments of the present invention to include a pin receptacle having an electrically conductive plating, where the pin receptacle is configured to receive an electrically conductive pin. The electrically conductive pin includes a surface and electrically conductive extrusions from the surface of the pin, with each extrusion extruding substantially orthogonal to a direction of insertion of the pin into the pin receptacle, where the extrusions configured to electrically couple, with parallel resistance, the pin to the electrically conductive plating of the pin receptacle.

Also described in this specification are methods of manufacturing a low resistance, multi-contact point pin, that include: providing an electrically conductive source material and stamping, from the electrically conductive source material, a pin that includes: a surface and electrically conductive extrusions from the surface of the pin, with each extrusion extruding substantially orthogonal to a direction of insertion of the pin into the pin receptacle, and where the extrusions are configured to electrically couple, with parallel resistance, the pin to the electrically conductive plating of the pin receptacle.

Also described in this specification are low resistance connectors that include low resistance, multi-contact point pins, where each pin includes: a surface and a electrically conductive extrusions from the surface of the pin, with each extrusion extruding substantially orthogonal to a direction of insertion of the pin into a pin receptacle, and where the extrusions are configured to electrically couple, with parallel resistance, the pin to the electrically conductive plating of the pin receptacle.

The foregoing and other objects, features and advantages of the invention will be apparent from the following more particular descriptions of exemplary embodiments of the invention as illustrated in the accompanying drawings wherein like reference numbers generally represent like parts of exemplary embodiments of the invention.

### BRIEF DESCRIPTION OF THE DRAWINGS

FIG. 1 sets forth a cross-section of a compliant pin of the prior art.

FIG. 2A sets forth a diagram of an exemplary low resistance, multi-contact point pin configured for insertion into a pin receptacle having an electrically conductive plating in accordance with embodiments of the present invention.

FIG. 2B sets forth a diagram of another exemplary low resistance, multi-contact point pin configured for insertion into a pin receptacle having an electrically conductive plating in accordance with embodiments of the present invention.

FIG. 3A depicts an example PCB configured to accept low resistance, multi-contact point pins configured in accordance with embodiments of the present invention.

FIG. 3B depicts a cross-section of an example PCB accepting low resistance, multi-contact point pins configured in accordance with embodiments of the present invention.

FIG. 4A sets forth a diagram of another exemplary low resistance, multi-contact point pin configured for insertion into a pin receptacle having an electrically conductive plating in accordance with embodiments of the present invention. For further explanation FIG. 4B sets forth a diagram of another exemplary low resistance, multi-contact point pin configured for insertion into a pin receptacle having an electrically conductive plating in accordance with embodiments of the present invention.

FIG. 5A depicts an example PCB configured to accept low resistance, multi-contact point pins implemented as power blade pins in accordance with embodiments of the present invention.

FIG. 5B depicts a cross-section of an example PCB accepting low resistance, multi-contact point pins configured as wide, power blade pins in accordance with embodiments of the present invention.

FIG. 6 sets forth a method of manufacturing a low resistance, multi-contact point pin in accordance with embodiments of the present invention.

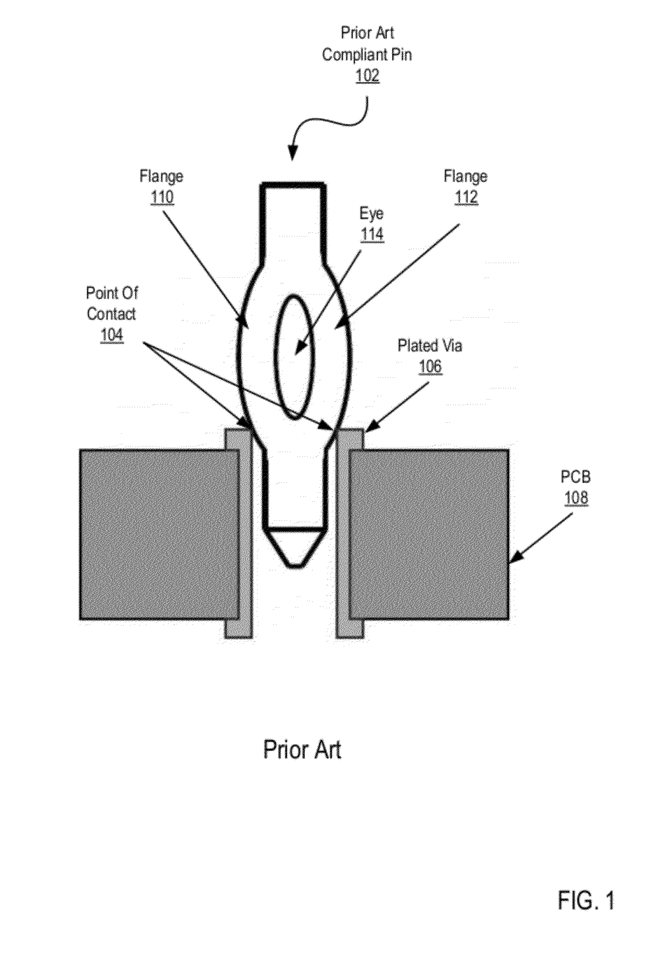

### DETAILED DESCRIPTION OF EXEMPLARY EMBODIMENTS

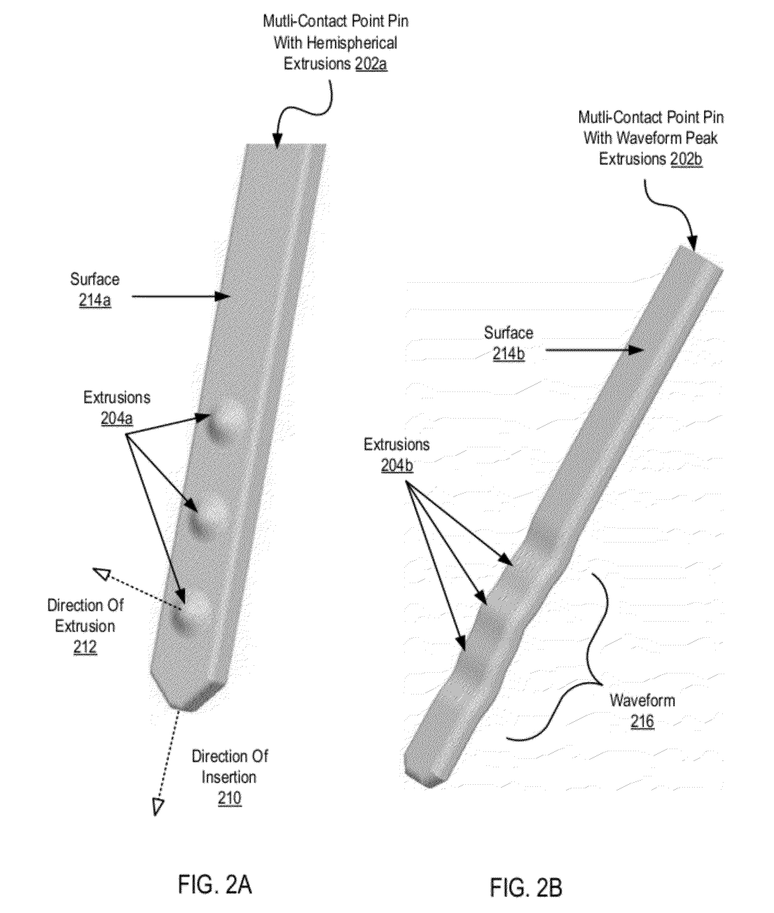

Exemplary pins, printed circuit boards, connectors, and methods of manufacturing pins for low resistance, multi-contact point electrical connection in accordance with the present invention are described with reference to the accompanying drawings, beginning with FIGS. 2A and 2B. FIG. 2A sets forth a diagram of an exemplary low resistance, multi-contact point pin configured for insertion into a pin receptacle having an electrically conductive plating in accordance with embodiments of the present invention.

The example multi-contact point pin (202a) of FIG. 2A includes a surface (214a) and a number of electrically conductive extrusions (204a) from the surface (214a) of the pin (202a). In the example of FIG. 2A, each extrusion (204a) is a hemisphere, or said another way, a ‘dot.’ In the example of FIG. 2A, each extrusion (204a) extrudes in a direction (212) substantially orthogonal to a direction (210) of insertion of the pin into the pin receptacle. The extrusions are configured to electrically couple, with parallel resistance, the pin to the electrically conductive plating of the pin receptacle. In contrast to prior art compliant pins that require multiple pins to lower resistance of a single electrical terminal connection, the example low resistance, multi-contact point pin (202a) of FIG. 2A may be configured to lower resistance by itself by providing multiple parallel points of contact. Although only three extrusions are depicted in the example pin (202a) of FIG. 2A for purposes of clarity, readers of skill in the art will recognize that multi-contact point pins configured in accordance with embodiments of the present invention for low-resistance applications may be implemented with any number of extrusions. Further, a low resistance connector—or terminal—may be implemented with more than one of the low resistance, multi-contact point pins of FIG. 2A.

FIG. 2B sets forth a diagram of another exemplary low resistance, multi-contact point pin configured for insertion into a pin receptacle having an electrically conductive plating in accordance with embodiments of the present invention. The example multi-contact point pin (202b) of FIG. 2B includes a surface (214b) and a number of electrically conductive extrusions (204b) from the surface (214b) of the pin (202b). In the example of FIG. 2A, each extrusion (204b) is a peak of a waveform. That is, at least a portion of the pin (202b) in the example of FIG. 2B is shaped as a waveform (216), with each peak of the waveform implementing an extrusion of the pin. In the example of FIG. 2B, each extrusion (204b) extrudes in a direction (212) substantially orthogonal to a direction (210) of insertion of the pin into the pin receptacle. The extrusions are configured to electrically couple, with parallel resistance, the pin to the electrically conductive plating of the pin receptacle. In contrast to prior art compliant pins that require multiple pins to lower resistance of a single electrical terminal connection, the example low resistance, multi-contact point pin (202b) of FIG. 2B may be configured to lower resistance by itself by providing multiple parallel points of contact. Although only three extrusions are depicted in the example pin (202b) of FIG. 2B for purposes of clarity, readers of skill in the art will recognize that multi-contact point pins configured in accordance with embodiments of the present invention for low-resistance applications may be implemented with any number of extrusions. Further, a low resistance connector—or terminal—may be implemented with more than one of the low resistance, multi-contact point pins of FIG. 2B.

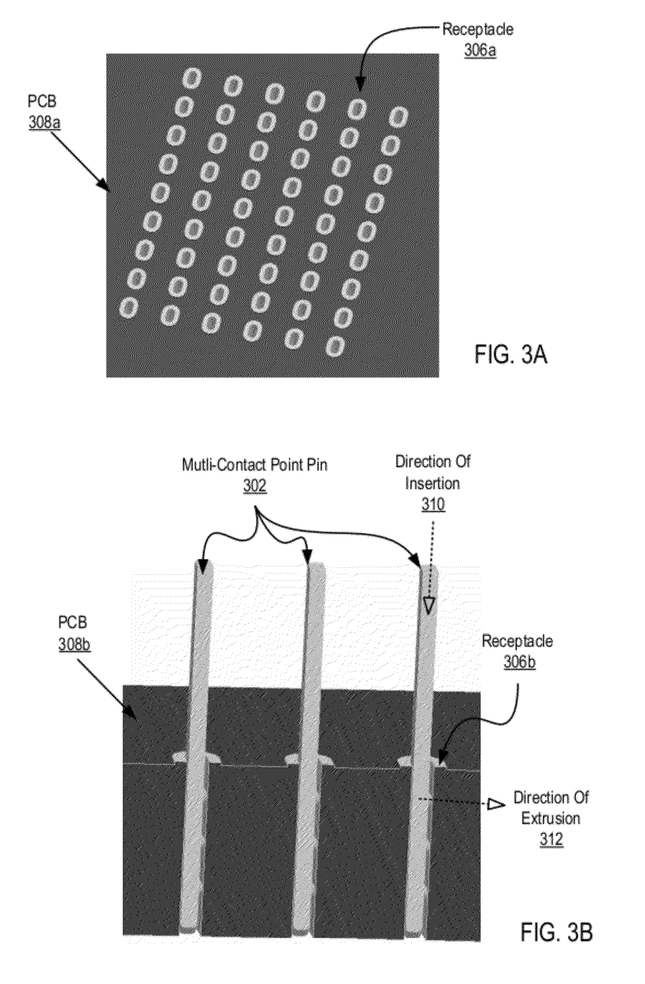

For further explanation, FIG. 3A depicts an example PCB configured to accept low resistance, multi-contact point pins configured in accordance with embodiments of the present invention. The example PCB (308a) of FIG. 3A includes an array of pin receptacles (306a) configured in a grid-like pattern. Each pin receptacle has an electrically conductive plating and is configured to receive an electrically conductive pin, such as the pins depicted in the example of FIG. 2A and FIG. 2B. The pin receptacles (306a) of the PCB (308a) of FIG. 3A are oval in shape, configured to receive a pin with only a single column of extrusions. Compared to plated through-hole vias configured to accept prior art compliant pins, each of the pin receptacles (306a) of FIG. 3A will be generally thinner in at least one dimension. As such, less area of the PCB will consumed by the pin receptacles of the present invention compared to the prior art pin receptacles. The extra area of the PCB may be useful for various reasons including, for example, by enabling a greater number of electrical traces to be etched between columns of the receptacles or by implementing a greater number of receptacles without consuming a greater area.

For further explanation, FIG. 3B depicts a cross-section of an example PCB accepting low resistance, multi-contact point pins configured in accordance with embodiments of the present invention. The example PCB (308b) of FIG. 3B includes three pin receptacles (306b). Each of the three pin receptacles (306b) has an electrically conductive plating and has received an electrically conductive pin (302). The pin (302) is a multi-contact point pin with a surface and more than one electrically conductive extrusion from the surface of the pin. Each of the extrusions extrudes in a direction (312) substantially orthogonal to a direction of insertion (310) of the pin (302) into the pin receptacle (306b). In the example of FIG. 3B, each pin receptacle is an oval shape and receives a pin (302) with only a single column of extrusions.

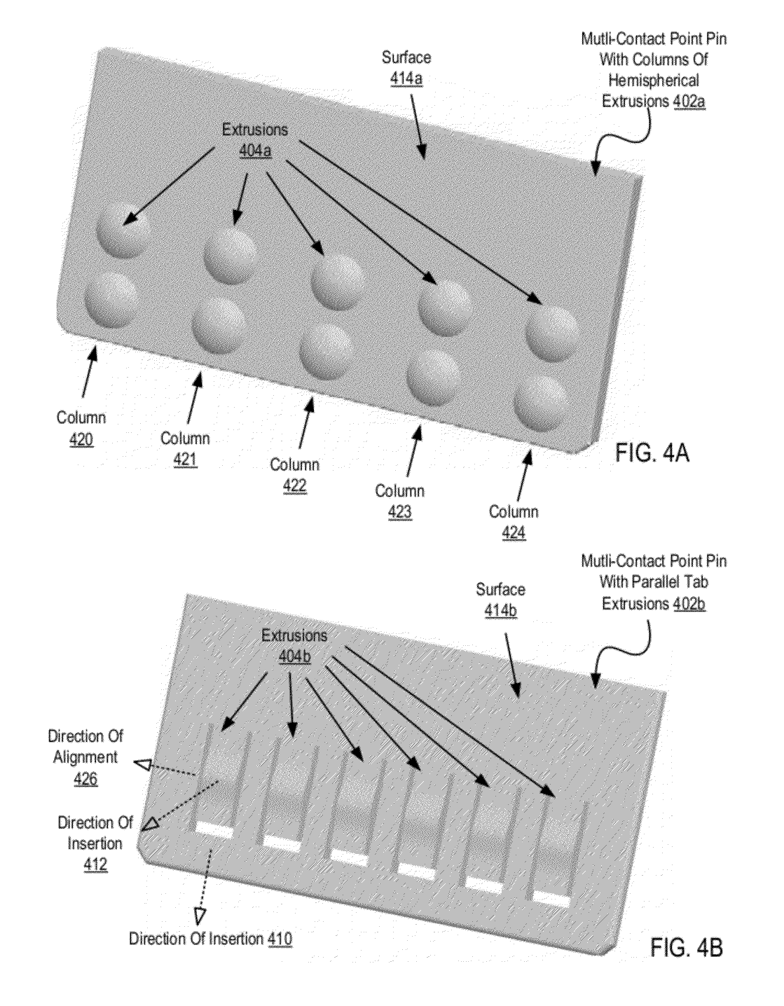

For further explanation FIG. 4A sets forth a diagram of another exemplary low resistance, multi-contact point pin configured for insertion into a pin receptacle having an electrically conductive plating in accordance with embodiments of the present invention. The example low resistance, multi-contact point pin (402a) of FIG. 4A is similar to the low resistance, multi-contact point pin (202a) of FIG. 2A in that the pin (402a) of FIG. 4A includes a surface (414a) and more than one electrically conductive extrusion (404a) from the surface (414a) of the pin (402a). Also, each extrusion (404a) of example pin (402a) of FIG. 4A extrudes in a direction substantially orthogonal to a direction of insertion of the pin into the pin receptacle and the extrusions are configured to electrically couple, with parallel resistance, the pin (402a) to the electrically conductive plating of the pin receptacle. Also like the example pin (202a) of FIG. 2A, the extrusions (404a) of pin (402a) of FIG. 4A are hemispherical. The pin of FIG. 4A differs from the pin (202a) of FIG. 2A, however, in that the pin (402a) of FIG. 4A is a pin of a power supply in a blade form factor and the extrusions (404a) are aligned in a number of columns (420-424) of extrusions. A power supply in a blade form factor may directly terminate or connect to a mid-plane, backplane, or some other direct interconnect. For such high-power applications, larger, or wider, pins may be utilized. In the example of FIG. 4A, such a wide, power blade type pin is depicted.

For further explanation FIG. 4B sets forth a diagram of another exemplary low resistance, multi-contact point pin configured for insertion into a pin receptacle having an electrically conductive plating in accordance with embodiments of the present invention. The example low resistance, multi-contact point pin (402b) of FIG. 4B is similar to the low resistance, multi-contact point pin (202a) of FIG. 2A in that the pin (402b) of FIG. 4B includes a surface (414b) and more than one electrically conductive extrusion (404b) from the surface (414b) of the pin (402b). Also, each extrusion (404b) of example pin (402b) of FIG. 4B extrudes in a direction (412) substantially orthogonal to a direction (410) of insertion of the pin (402b) into the pin receptacle and the extrusions are configured to electrically couple, with parallel resistance, the pin (402b) to the electrically conductive plating of the pin receptacle. The pin of FIG. 4B differs from the pin (202a) of FIG. 2A, however, in that the pin (402b) of FIG. 4B is a pin of a power supply in a blade form factor and each of the extrusions (414b) is implemented as a tab extrusion. The extrusions (404b) of the example pin (402b) of FIG. 4B are aligned parallel to one another and in a direction (426) orthogonal to the direction (410) of insertion of the pin into the pin receptacle.

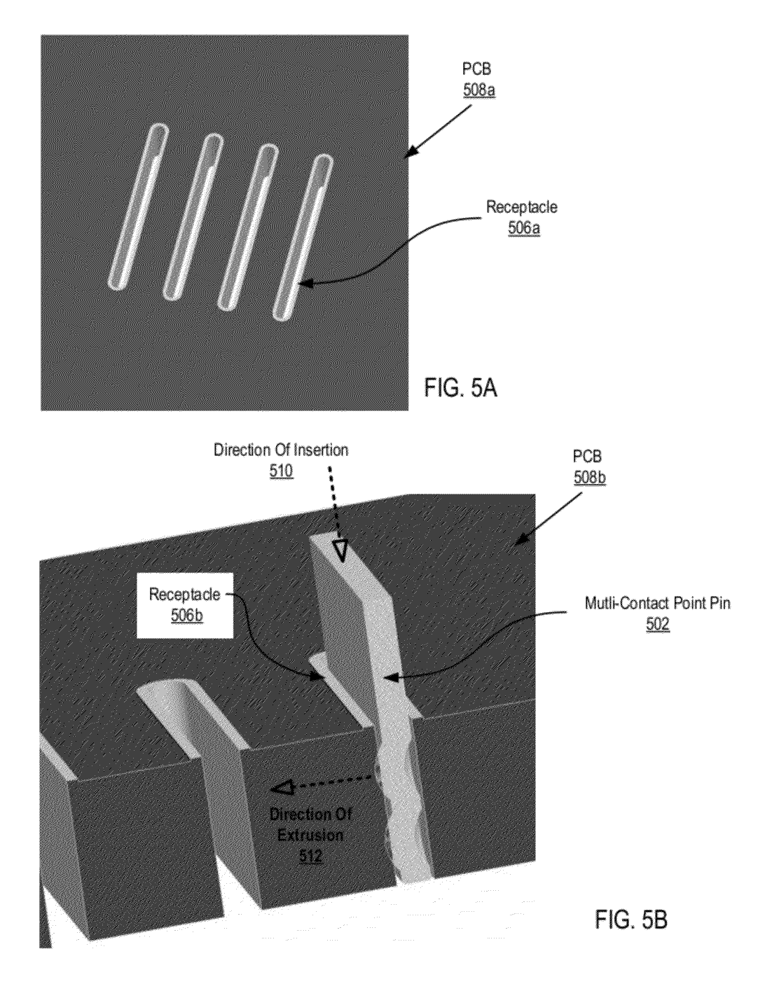

For further explanation, FIG. 5A depicts an example PCB configured to accept low resistance, multi-contact point pins implemented as power blade pins in accordance with embodiments of the present invention. The example PCB (508a) of FIG. 5A is similar to the PCB (308a) of FIG. 3A in that the PCB (508a) of FIG. 5A includes several pin receptacles (506a) with each having an electrically conductive plating. Each of the pin receptacles (506a) of the example PCB (508a) of FIG. 5A is configured to receive an electrically conductive pin that includes a surface and more than one electrically conductive extrusion from the surface of the pin, with each extrusion extruding substantially orthogonal to a direction of insertion of the pin into the pin receptacle (506a), and the extrusions configured to electrically couple, with parallel resistance, the pin to the electrically conductive plating of the pin receptacle. The example PCB (508a) of FIG. 5A differs from the PCB (308a) of FIG. 3A, however, in that the example pin receptacles (506a) of FIG. 5A are oval shape and configured to receive a pin with more than one column of extrusions. The example pin receptacles (506a) of FIG. 5A, for example, are each configured to receive a pin similar to those depicted in the example of FIG. 4A and FIG. 4B—the wide, power blade pins with hemispheric or tab extrusions.

For further explanation, FIG. 5B depicts a cross-section of an example PCB accepting low resistance, multi-contact point pins configured as wide, power blade pins in accordance with embodiments of the present invention. The example PCB (508b) of FIG. 5B includes three pin receptacles (506b). Each of the three pin receptacles (506b) has an electrically conductive plating and one of the receptacle (506b) has received an electrically conductive pin (502). The pin (502) is a multi-contact point pin with a surface and more than one electrically conductive extrusion from the surface of the pin. Each of the extrusions extrudes in a direction (512) substantially orthogonal to a direction of insertion (510) of the pin (502) into the pin receptacle (506b). In the example of FIG. 5B, each pin receptacle is an oval shape and receives a pin (502) with more than one column of extrusions.

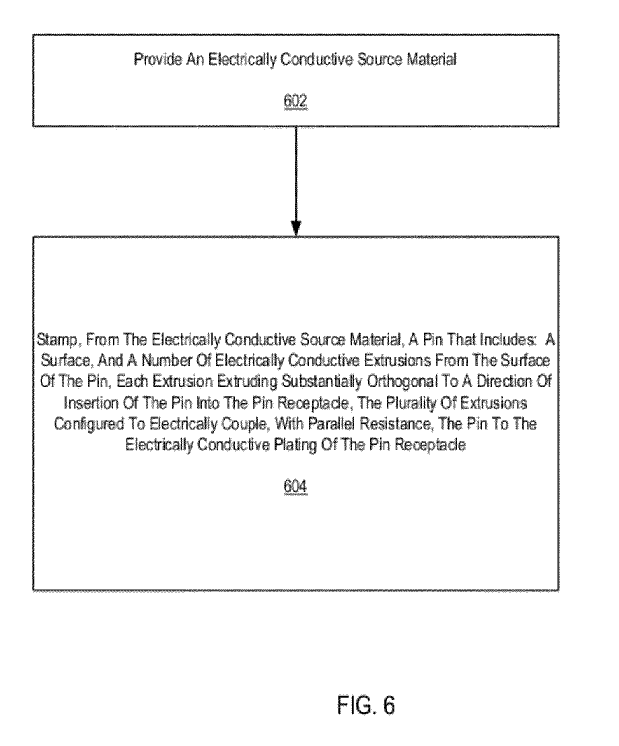

For further explanation, FIG. 6 sets forth a method of manufacturing a low resistance, multi-contact point pin in accordance with embodiments of the present invention. The method of FIG. 6 includes providing (602) an electrically conductive source material. Providing (602) an electrically conductive source material may be carried out by providing a sheet metal, such as gold, copper, bronze, silver, phosphor bronze copper alloy, or other electrically conductive metal-based material.

The method of FIG. 6 continues by stamping (604), from the electrically conductive source material, a pin. In the method of FIG. 6, the stamped pin includes a surface and more than one electrically conductive extrusion from the surface of the pin, with each extrusion extruding in a direction substantially orthogonal to a direction of insertion of the pin into the pin receptacle, and where the extrusions are configured to electrically couple, with parallel resistance, the pin to the electrically conductive plating of the pin receptacle. Stamping may include a variety of sheet-metal forming manufacturing processes, such as punching using a machine press or stamping press, blanking, embossing, bending, flanging, and coining. Stamping may be carried out in a single stage operation where every stroke of a press produces the desired form on the sheet metal part, or may occur through a series of stages.

It will be understood from the foregoing description that modifications and changes may be made in various embodiments of the present invention without departing from its true spirit. The descriptions in this specification are for purposes of illustration only and are not to be construed in a limiting sense. The scope of the present invention is limited only by the language of the following claims.

What is claimed is:

1. A low resistance, multi-contact point pin, the pin configured for insertion into a pin receptacle having an electrically conductive plating, the pin comprising:
a surface; and
a plurality of electrically conductive extrusions from the surface of the pin, each extrusion extruding substantially orthogonal to a direction of insertion of the pin into the pin receptacle, the plurality of extrusions configured to electrically couple, with parallel resistance, the pin to the electrically conductive plating of the pin receptacle.

2. The pin of claim 1 wherein each extrusion comprises a hemisphere.

3. The pin of claim 1 wherein each extrusion comprises a peak of a waveform.

4. The pin of claim 1 wherein:
the plurality of extrusions are aligned in a single column in the direction of insertion of the pin into the pin receptacle.

5. The pin of claim 1 wherein:
the pin further comprises a pin of a power supply in a blade form factor; and
the plurality of extrusions are aligned in a plurality of columns of extrusions.

6. The pin of claim 1 wherein:
the pin further comprises a pin of a power supply in a blade form factor;
each of the plurality of extrusions comprises a tab extrusion; and
the plurality of extrusions are aligned parallel to one another and orthogonal to the direction of insertion of the pin into the pin receptacle.

7. A printed circuit board comprising:
a pin receptacle having an electrically conductive plating, the pin receptacle configured to receive an electrically conductive pin, the pin comprising:
a surface, and
a plurality of electrically conductive extrusions from the surface of the pin, each extrusion extruding substantially orthogonal to a direction of insertion of the pin into the pin receptacle, the plurality of extrusions configured to electrically couple, with parallel resistance, the pin to the electrically conductive plating of the pin receptacle.

8. The printed circuit board of claim 7, wherein:
the pin receptacle comprises a plated, through-hole via.

9. The printed circuit board of claim 7, wherein:
the pin receptacle comprises an oval shape configured to receive a pin with only a single column of extrusions.

10. The printed circuit board of claim 7, wherein:
the pin receptacle comprises an oval shape configured to receive a pin with a plurality of columns of extrusions.

11. The printed circuit board of claim 7, wherein:
the pin receptacle comprises an oval shape configured to receive a pin with the plurality of extrusions aligned parallel to one another and orthogonal to the direction of insertion of the pin into the pin receptacle.

12. A method of manufacturing a low resistance, multi-contact point pin, the method comprising:
providing an electrically conductive source material; and
stamping, from the electrically conductive source material, a pin, wherein the pin comprises:
a surface, and
a plurality of electrically conductive extrusions from the surface of the pin, each extrusion extruding substantially orthogonal to a direction of insertion of the pin into the pin receptacle, the plurality of extrusions configured to electrically couple, with parallel resistance, the pin to the electrically conductive plating of the pin receptacle.

13. The method of claim 12 wherein each extrusion comprises a hemisphere.

14. The method of claim 12 wherein each extrusion comprises a peak of a waveform.

15. The method of claim 12 wherein:
the plurality of extrusions are aligned in a single column in the direction of insertion of the pin into the pin receptacle.

16. The method of claim 12 wherein:
the pin further comprises a pin of a power supply in a blade form factor; and
the plurality of extrusions are aligned in a plurality of columns of extrusions.

17. The method of claim 12 wherein:
the pin further comprises a pin of a power supply in a blade form factor;
each of the plurality of extrusions comprises a tab extrusion; and
the plurality of extrusions are aligned parallel to one another and orthogonal to the direction of insertion of the pin into the pin receptacle.

18. A low resistance connector comprising:
a plurality of low resistance, multi-contact point pins, wherein each pin comprises:
a surface, and
a plurality of electrically conductive extrusions from the surface of the pin, each extrusion extruding substantially orthogonal to a direction of insertion of the pin into a pin receptacle, the plurality of extrusions configured to electrically couple, with parallel resistance, the pin to the electrically conductive plating of the pin receptacle.

19. The connector of claim 18 wherein each extrusion comprises a hemisphere.

20. The connector of claim 18 wherein each extrusion comprises a peak of a waveform.

21. The connector of claim 18 wherein:
the plurality of extrusions of each pin are aligned in a single column in the direction of insertion of the pin into the pin receptacle.

22. The connector of claim 18 wherein:
each pin further comprises a pin of a power supply in a blade form factor; and
the plurality of extrusions are aligned in a plurality of columns of extrusions.

23. The connector of claim 18 wherein:
each pin further comprises a pin of a power supply in a blade form factor;
each of the plurality of extrusions comprises a tab extrusion; and
the plurality of extrusions are aligned parallel to one another and orthogonal to the direction of insertion of the pin into the pin receptacle.
